(19) United States
(12) Patent Application Publication
(10) Pub. No.: US 2016/0073518 A1
(43) Pub. Date: Mar. 10, 2016

(54) FRONT PLATE FOR DISPLAY DEVICE AND DISPLAY DEVICE HAVING THE SAME

(71) Applicant: MITSUBISHI ELECTRIC CORPORATION, Tokyo (JP)

(72) Inventor: Yuki SATO, Tokyo (JP)

(73) Assignee: MITSUBISHI ELECTRIC CORPORATION, Tokyo (JP)

(21) Appl. No.: 14/830,490

(22) Filed: Aug. 19, 2015

(30) Foreign Application Priority Data
Sep. 5, 2014 (JP) 2014-180713

(51) Int. Cl. H05K 5/00; A47B 81/06

(52) U.S. Cl. CPC H05K 5/0017; A47B 81/06

(57) ABSTRACT

A display-device front plate having a rectangular outer shape and formed of a transparent material, the display-device front plate includes a printed part, which has at least two layers provided on a principal surface of the display-device front plate and which has a frame-shape, wherein the printed part comprises: a first printed portion, which is formed on the principal surface; and a second printed portion, which is formed at a position overlapping with the first printed portion and which is formed on the first printed portion at the principal surface of the display-device front plate, and wherein the shape of the second printed portion which is located inside a region of the first printed portion is different from the first printed portion.

### CROSS-REFERENCE TO RELATED APPLICATION

This application claims priority from Japanese Patent Application No. 2014-180713 filed on Sep. 5, 2014, the entire subject matter of which is incorporated herein by reference.

### TECHNICAL FIELD

The present invention relates to a front plate (hereinafter, referred to as a “display-device front plate”) for a display device and the display device having the same. The display-device front plate is placed on a front surface of the display device.

### BACKGROUND

With the recent spread of information electronic devices, a display device that includes a display-device front plate having toughness and a touch panel on a front surface of a display panel has been widely spread. There is a case where printing is applied to an outer peripheral portion thereof so that the display-device front plate placed on the front surface of the display panel has a high design property. In this case, the print width may be different on each side. Since the display-device front plate with a printed outer peripheral portion has different print widths on each side, it is necessary to correctly arrange the display-device front plate in the vertical direction and lateral direction when bonding to the display panel. However, when the difference between the print widths is fine, it may be difficult to discriminate the display-device front plate in the vertical direction and lateral direction.

In the display-device front plate disclosed in JP-A-2011-203317, a colored layer is provided at an outer peripheral portion on a substrate surface of a transparent substrate having a rectangular outer shape and an invisible position identification mark is provided in the portion of the colored layer. The invisible position identification mark is difficult to be visually discriminated as the colored layer, as seen in a plan view.

According to the configurations of the display-device front plate disclosed in JP-A-2011-203317, the invisible position identification mark for discriminating the display-device front plate in the vertical direction and lateral direction has a structure that is difficult to be visually discriminated. Therefore, a specific device is required for the discrimination. Furthermore, there is a problem that a process for making the invisible position identification mark, such as a process of forming a non-formation portion in the colored layer and a process of embedding the non-formation portion, is required.

The present invention is to provide a display-device front plate where the arrangement position of the display-device front plate in the vertical direction and lateral direction can be visually discriminated and suppresses a special process for forming this configuration.

### SUMMARY

A display-device front plate of this disclosure has a rectangular outer shape and formed of a transparent material, and the display-device front plate includes a printed part, which has at least two layers provided on a principal surface of the display-device front plate and which has a frame-shape, wherein the printed part comprises: a first printed portion, which is formed on the principal surface; and a second printed portion, which is formed at a position overlapping with the first printed portion and which is formed on the first printed portion at the principal surface of the display-device front plate, and wherein the shape of the second printed portion which is located inside a region of the first printed portion is different from the first printed portion.

According to the configurations of the present invention, the arrangement position of the display-device front plate in the vertical direction and lateral direction can be visually discriminated and a special process for forming this configuration can be suppressed.

### BRIEF DESCRIPTION OF THE DRAWINGS

The foregoing and additional features and characteristics of this disclosure will become more apparent from the following detailed descriptions considered with the reference to the accompanying drawings, wherein:

FIG. 1 is a rear view of a display-device front plate of the present invention; and

FIG. 2 is an exploded perspective view of a display device including the display-device front plate shown in FIG. 1.

### DETAILED DESCRIPTION

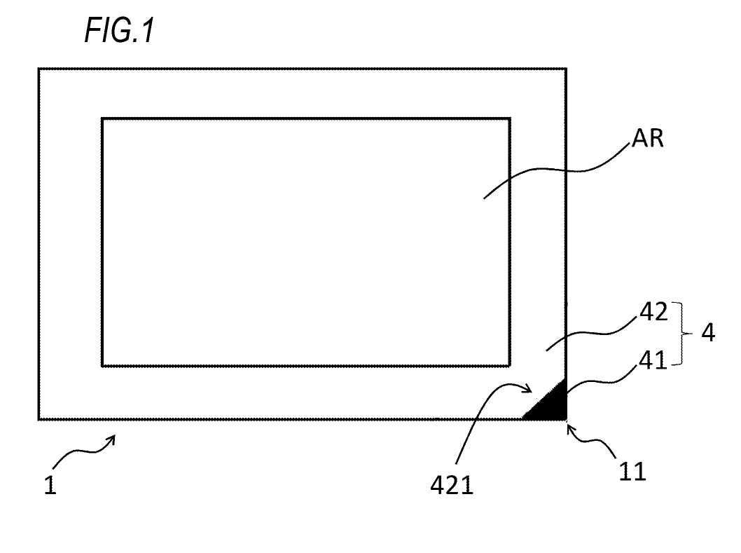

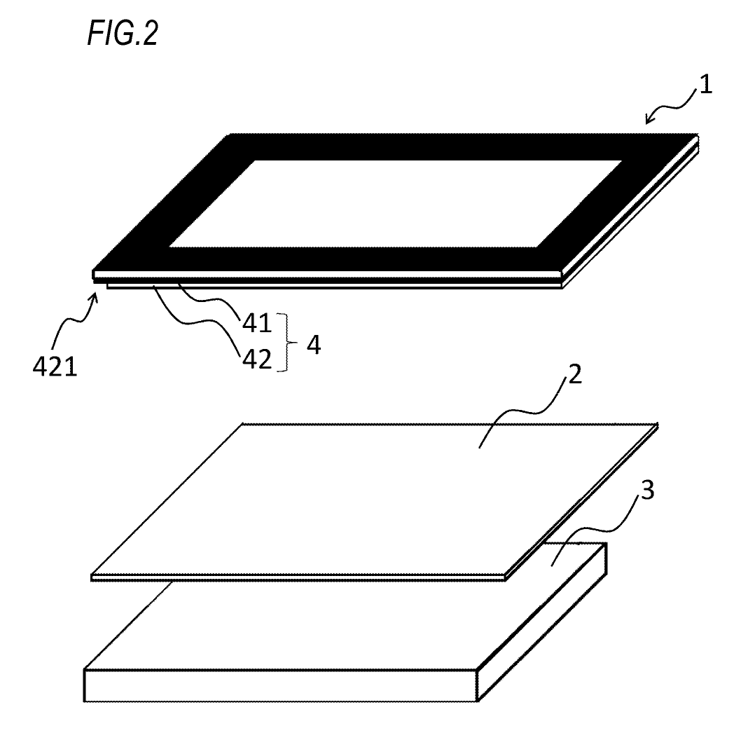

Hereinafter, a display-device front plate of the present invention will be described with reference to the drawings. FIG. 1 is a rear view of the display-device front plate of the present invention. FIG. 2 is an exploded perspective view of a display device including the display-device front plate shown in FIG. 1. As shown in the exploded perspective view of FIG. 2, in the display device of the present invention, a touch panel 2 and a display-device front plate 1 are placed on a front surface of a display device 3.

### Display-Device Front Plate

For the purpose of suppressing the damage, deformation, wear and dirt or the like due to pressure or contact from the outside, the display-device front plate 1 is placed so as to face a front surface side (operating surface side) of the touch panel 2 or a front surface side (display surface side) of the display device 3. The display-device front plate 1 is formed of a substantially transparent material such as glass or plastic. In the present embodiment, the display-device front plate 1 is formed of glass that has a high strength and is hardly deformed. Further, when being placed on the touch panel 2, the thickness of the display-device front plate 1 used is thicker than that of the touch panel 2. When the display-device front plate 1 has the thickness generally two or more times greater than that of the touch panel 2, the deformation or damage can be avoided. Further, by performing a printing or painting operation on a front surface or rear surface of the display-device front plate 1, a function as a design member may be added to the display-device front plate 1. In the present invention, the display-device front plate 1 is placed on the front surface of the touch panel 2.

### Touch Panel

The touch panel 2 converts information on a position coordinate inputted from the outside (operator) into an electrical signal by a circuit configured by a transparent electrode formed on a transparent substrate. Then, the touch panel 2 transmits the electrical signal to a control circuit of a final product by an output wiring member (not shown). In the present embodiment, the touch panel 2 employs a projection capacitance type. In the projection capacitance type touch panel 2, a position of a fingertip or the like of an operator is detected by a coordinate data and a ratio of the current amount according to a contact position and a plurality of electrode patterns in the vicinity of the contact position is measured. In this way, the position of the fingertip is precisely determined, so that a signal input is performed. Further, a transparent glass or the like is used as an upper substrate and a lower substrate, which constitute the touch panel 2.

### Display Device

The display device 3 is configured by a display panel for displaying an image and an illumination device for illuminating the display panel, as necessary. A liquid crystal display panel or the like is used as the display panel.

As shown in the rear view of the display-device front plate 1 of FIG. 1, in the embodiment of the present invention, the display-device front plate 1 has a rectangular shape and a frame-shaped printed part 4 is formed so as to surround a display area AR of the display device 3 which is disposed below the display-device front plate 1. In the present embodiment, the printed part 4 is formed of at least two layers. As a first layer, a first printed portion 41 is formed on a rear surface that is one principal surface of the display-device front plate 1. Further, as a second layer, a second printed portion 42 is formed at a position located inside a region of the first printed portion 41 and overlapping with the first printed portion 41. The second printed portion 42 is formed such that a portion located at a peripheral end portion of the display-device front plate 1 has a shape different from the first printed portion 41. In the present embodiment, in the four corners of the second printed portion 42, a cutout 421 in which the second printed portion 42 is absent is provided at outer peripheral end portion of one corner 11.

Subsequently, the display-device front plate 1 configured as described above is fixed to the touch panel 2 by a bonding member, and then the bonded plate is bonded to a front surface of the display device 3. At this time, the cutout 421 provided in the one corner 11 of the display-device front plate 1 is visually discriminated, and thus, the display-device front plate 1 can be bonded to the display device 3 without causing erroneous arrangement position of the display-device front plate 1 in the vertical direction and lateral direction. Alternatively, the formation position of the cutout 421 can be discriminated by a simple automatic bonding device or the like, and thus, the arrangement position of the display-device front plate 1 in the vertical direction and lateral direction can be discriminated, thereby performing a bonding operation.

As described above, in the display device of the present invention, the printed part 4 placed in the rear surface side of the display-device front plate 1 is formed by overlapping at least two layers. The first printed portion 41 and the second printed portion 42 are formed in different shapes. Therefore, upon bonding the display-device front plate 1 to the display device 3 (or the touch panel 2), the position of the different shape of the second printed portion 42 can be checked and the arrangement position in the vertical direction and lateral direction can be visually discriminated. The different shape is configured as the cutout 421, which is provided inside the region of the first printed portion 41 and in which a portion of the second printed portion 42 is absent. The cutout 421 is formed in the one corner 11 of the second printed portion 42. Therefore, it is easy to visually check the arrangement position. Further, a process of forming the different shape is executed simply by changing the shape of a portion of the second printed portion 42 that is formed so as to overlap with the first printed portion 41. As a result, a special process can be suppressed from being added.

As shown in the drawings, the cutout 421 may have a configuration that the cutout 421 is formed from the outer peripheral portion. However, depending on the design required, a hole shape may be employed, instead of the cutout 421. Further, the cutout 421 or the hole may be formed from the display area AR side. At this time, since the cutout 421 is formed in the one corner 11 of the outer peripheral end portion of the second printed portion 42, light reaching the display-device front plate 1 from the display device 3 is blocked by the first printed portion 41. As a result, it is possible to suppress the light from being leaked to the front surface of the display-device front plate 1. Further, it is also possible to suppress the cutout 421 from being recognized from the front surface side.

Further, as a modified example, the cutout 421 of the one corner 11 of the second printed portion 42 may be formed such that a corner of the cutout 421 is formed as a curve, i.e., R shape.

As the material of the printed part 4, a black printing member may be employed. The second printed portion 42 may be formed in a color other than black. The first printed portion 41 and the second printed portion 42 may be suitably formed in colors other than black, depending on the design properties. Since the first printed portion 41 and the second printed portion 42 are formed in different colors, the cutout 421 provided in the second printed portion 42 can be visually discriminated more easily. Further, the printed part 4 may be formed by printing or painting a print material having a light-shielding property or may be formed by overlapping a tape having a print light-shielding property. Further, as the materials of the first printed portion 41 and the second printed portion 42, different materials may be appropriately selected.

What is claimed is:

1. A display-device front plate having a rectangular outer shape and formed of a transparent material, the display-device front plate comprising:
a printed part, which has at least two layers provided on a principal surface of the display-device front plate and which has a frame-shape, wherein the printed part comprises:
a first printed portion, which is formed on the principal surface; and
a second printed portion, which is formed at a position overlapping with the first printed portion and which is formed on the first printed portion at the principal surface of the display-device front plate, and
wherein the shape of the second printed portion which is located inside a region of the first printed portion is different from the first printed portion.

2. The display-device front plate according to claim 1,
wherein the shape of the second printed portion, which is located inside the region of the first printed portion, is a shape having a cutout or a hole at one corner of the display-device front plate.

3. The display-device front plate according to claim 2,
wherein the cutout or the hole is formed in an outer peripheral portion of the second printed portion.

4. The display-device front plate according to claim 1,
wherein the first printed portion and the second printed portion are formed of colored members with different colors.

5. A display device comprising:
wherein the display-device front plate according to claim 1,
wherein the principal surface formed with the printed part is placed so as to face a display surface of the display device for displaying an image.
